(19) United States
(12) Patent Application Publication
(10) Pub. No.: US 2002/0093109 A1
(43) Pub. Date: Jul. 18, 2002

(54) Composition and method for containing metal ions in electronic devices

(76) Inventor: Eric Vance Kline, Clinton Corners, NY (US)

Correspondence Address: MCGINN & GIBB, PLLC, 8321 OLD COURTHOUSE ROAD, SUITE 200, VIENNA, VA, 22182-3817, US

(21) Appl. No.: 09/759,018

(22) Filed: Jan. 12, 2001

(51) Int. Cl. H01L 23/29; H01L 23/31

(52) U.S. Cl. 257/787; 257/788; 438/126

(57) ABSTRACT

A composition for containing metal ions in an electronic device includes an immobile particle and a chelating agent which is bonded to the immobile particle. The chelating agent complexes with metal ions that leach out of metal sources within the electronic device so that the metal ions are prevented from entering an aqueous environment when the electronic device is discarded.

### BACKGROUND OF THE INVENTION

1. Field of the Invention

The present invention generally relates to a composition and method for containing metal ions in electronic devices and more specifically to a composition and method for containing metal ions in electronic devices which utilizes an immobile chelating agent.

2. Description of the Related Art

Conventional electronics devices use metal solders to interconnect electronic components. However, such solders typically contain heavy metals (e.g., lead and tin) and, therefore, present environmental concerns. For example, after the soldering process, residual solder materials are cleaned from the printed circuit board (PCB) using liquid cleaning solvents which generates heavy metal containing waste. In addition, the metals in the solder may be soluble in water so that discarded PCBs pose a ground water contamination problem.

A first conventional method uses a solder paste which is intended to alleviate the environmental concerns of such solders. The paste includes a fusible, solderable metal alloy and a polymerizable, crosslinkable, thermosetting composition polymer formulation which acts as a fluxing agent and adheres to the molten metal while it is being cured. When the paste is heated the metal particles fuse and the resin encapsulates the fused metal and cures as a solid polymer film on the surface of the fused metal. The paste also includes a chelating agent to promote adhesion of the polymer film to the molten metal surface during cure by chelating metal ions formed as a result of the fluxing process.

However, in the above-mentioned paste, the chelating agent is not intended to complex with contaminant heavy metal species. In fact, the chelating agent is not present in the above-mentioned paste in high enough quantities to perform this function.

Moreover, even if the chelating agent in the above-mentioned paste was present in a sufficient quantity and in fact, did complex with contaminant heavy metal species, the chelating agents are not chemically bonded to an insoluble or immobile structure. Therefore, the above-mentioned solder paste would not render native heavy metal ions harmless by preventing egress into an aqueous environment.

### SUMMARY OF THE INVENTION

In view of the foregoing disadvantages of the conventional method, an object of the present invention is to provide a composition and method for containing metal ions in electronic devices which utilizes an immobile metal complex.

In a preferred embodiment, a composition for containing metal ions in an electronic device includes (preferably, consists essentially of) an immobile particle and chelating agents (i.e., chemically active agents) which are bonded to the immobile particle. The chelating agents complex with metal ions that leach out of metal sources within the electronic device. The chelating agents may include, for example, oxylate, ethylenediamine, ethylenediamine tetraacetate or other chemically active agents.

In another aspect of the present invention, an electronic device has an integrated circuit with the inventive composition. The composition may be contained within a scratch coat covering an active surface of the integrated circuit.

In another aspect of the present invention, the electronic device has a package, to which the integrated circuit is bonded and the inventive composition is contained within an encapsulant which is deposited over the surface of the integrated circuit and the package. The composition may alternatively be contained within an underfill which is deposited between the integrated circuit and the package. Alternatively, the inventive composition may be contained within an organic package.

In another aspect of the present invention, the inventive composition is contained within an underfill which is deposited between the package and a printed circuit board. Alternatively, the composition may be contained within the printed circuit board or contained within a conformal coating which is deposited over the integrated circuit, package and printed circuit board.

In another aspect, an inventive method of containing metals in an electronic product includes bonding a chelating agent to an immobile particle to form a composite, depositing the composite in close proximity to a metal source, and using the chelating agent to capture metal ions which leach out of the metal source.

With its unique and novel features and designs, the inventive composition and method provide a means for preventing metal ions from leaching out of an electronic device and into an aqueous environment when the device is discarded, thereby alleviating environmental concerns about discarded electronic devices.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a schematic drawing of a composition for containing metal ions in electronic devices according to a preferred embodiment of the present invention;

FIG. 2 is a structural formula for a chelating agent which may be used in a composition for containing metal ions in electronic devices according to a preferred embodiment of the present invention;

FIG. 3 is a schematic drawing of an integrated circuit having a scratch coat which contains a composition for containing metal ions in electronic devices according to a second aspect of a preferred embodiment of the present invention;

FIG. 4 is a schematic drawing of an integrated circuit having an encapsulant which contains a composition for containing metals ions in electronic devices according to a third aspect of a preferred embodiment of the present invention;

FIG. 5 is a schematic drawing of an integrated circuit having an underfill which contains a composition for containing heavy ions in electronic devices according to a fourth aspect of a preferred embodiment of the present invention;

FIG. 6 is a schematic drawing of an integrated circuit bonded to a package which contains a composition for containing metal ions in electronic devices according to a fifth aspect of a preferred embodiment of the present invention;

FIG. 7 is a schematic drawing of an integrated circuit which has a package underfill which contains a composition for containing metal ions in electronic devices according to a sixth aspect of a preferred embodiment of the present invention;

FIG. 8 is a schematic drawing of an integrated circuit and package which are bonded to a printed circuit board which contains a composition for containing metal ions in electronic devices according to a seventh aspect of a preferred embodiment of the present invention;

FIG. 9 is a schematic drawing of an integrated circuit, package and printed circuit board having a conformal coating which contains a composition for containing metal ions in electronic devices according to an eighth aspect of a preferred embodiment of the present invention; and

FIG. 10 is a flow diagram illustrating a preferred method of containing metal ions in electronic devices according to a preferred embodiment of the present invention.

### DETAILED DESCRIPTION OF PREFERRED EMBODIMENTS OF THE INVENTION

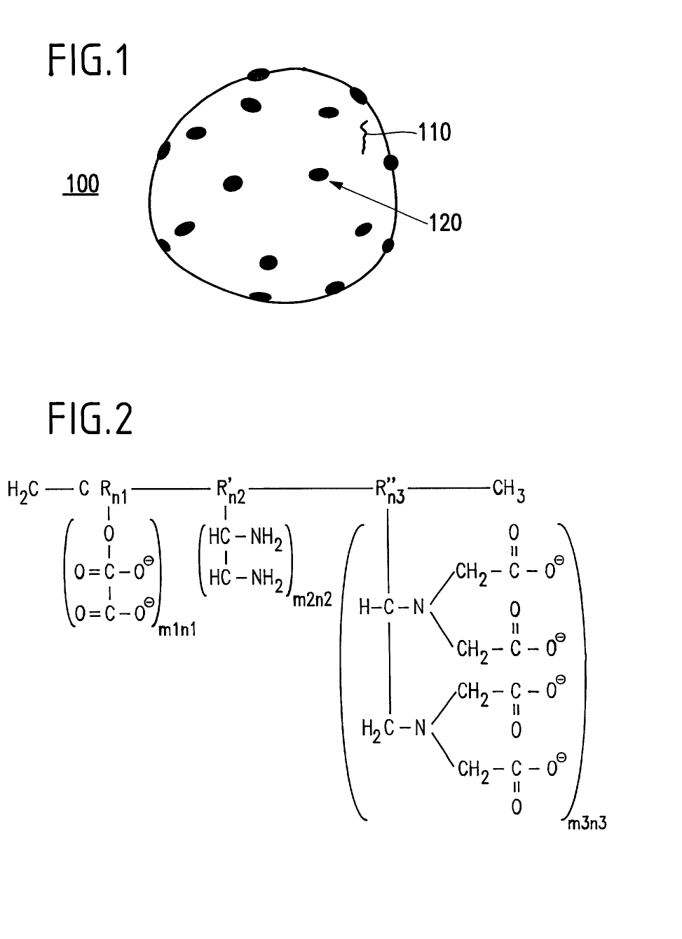

Referring now to the drawings, FIG. 1 is a schematic drawing of a composition for containing metal ions in electronic devices according to a preferred embodiment of the present invention. As shown in FIG. 1, the inventive composition 100 includes a very high molecular weight insoluble and immobile particle 110 and a chelating agent 120 which is permanently bonded to the immobile particle 110.

Chelating agents are chemicals which are used to extract metals from solution. Chelating agents bond easily with metals to form thermodyamically stable organometallic complexes. A variety of chelating agents such as ethylenediamine tetraacetate (EDTA) are well known in the art and may be used in the inventive composition 100.

Specifically, the chelating agent 120 may have a single chelating group in a general mode (i.e., the chelating agent will bond with any available cation species (within certain parameters such as valence state, etc.)). A chelating agent with a single chelating group in a cation specific mode (i.e., the chelating agent will bond only with specific cations) may also be used. Such an agent may be desired for example, where it is desired to contain a target metal having a high toxicity but which is at low concentrations.

In addition, the inventive composition 100 may utilize a chelating agent 120 having multiple chelating groups (i.e., two or more chelating groups) in the general and specific modes as described above.

FIG. 2 shows a structural formula for a chelating agent which may be used in a composition for containing metal ions in electronics products according to a preferred embodiment of the present invention. Specifically, the chelating agent in FIG. 2 has multiple chelating groups (i.e., oxalate, ethylenediamine, and ethylenediamine tetraacetate).

The chelating agent 120 should be present in the inventive composition 100 in a sufficient quantity to capture substantially all of the metals which may potentially leach out of the solder and into an aqueous environment. In addition, the immobile particle 110 should be located in close proximity to the metal source (e.g., the solder joints of electronic components) and/or between the metal source and the environment, in such a way as to present both a physical and chemical barrier to contaminant egress. As a result, when the circuit board is placed in an aqueous environment and a metal ion leaches out of the solder, the ion will bond to the chelating agent 120 to form an organometallic complex (i.e., a metal chelate) which cannot move into the aqueous environment because the chelating agent 120 is also bonded to the immobile particle 120.

Moreover, the organometallic complex could be made insoluble in water. In this way, even if the organometallic complex would separate from the immobile particle 120, the potential harm to the environment is significantly reduced because the complex is insoluble.

The resulting organometallic complex may be made insoluble by choosing the chelating agent appropriately (i.e., by choosing a chelating agent that forms an insoluble complex with the metals of interest). Alternatively, the complex itself may be soluble but made insoluble by chemically altering the complex in a secondary reaction.

The inventive composition 100 may be applied to a printed circuit board in a variety of ways so as to provide a chemical and physical barrier to metals which would otherwise leach from the discarded electronic product into an aqueous environment.

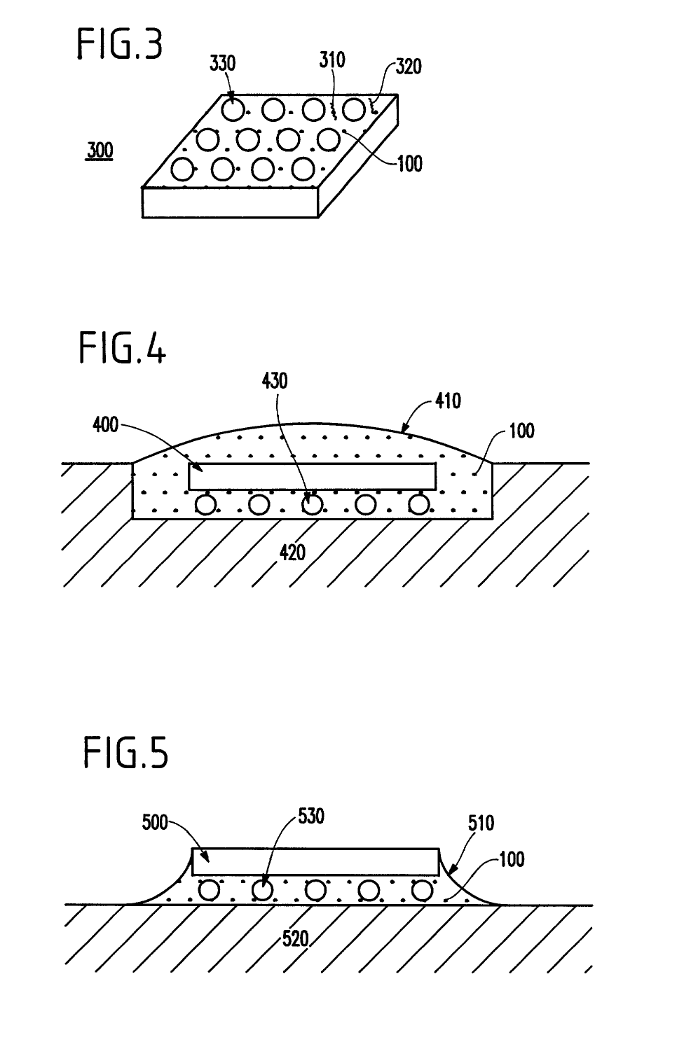

For example, FIG. 3 is a schematic drawing of an integrated circuit 300 containing a composition for containing metal ions in electronic devices according to a first aspect of a preferred embodiment of the present invention. As shown in FIG. 3, the inventive composition 100 may be contained in a scratch coat 310 which covers the active surface 320 of the integrated circuit 300. The scratch coat 310 may be any conventional scratch coat material and applied to the active surface 320 so as to cover the solder 330.

FIG. 4 is a schematic drawing of a integrated circuit 400 containing a composition for containing metal ions in electronic devices according to a second aspect of a preferred embodiment of the present invention. As shown in FIG. 4, the inventive composition 100 may be contained in an encapsulant 410 which surrounds the entire integrated circuit 400 and package 420 so as to present a continuous and congruent physical and chemical barrier to contaminant ion egress. The encapsulant 410 material may be any conventional encapsulant material and applied to the entire surface of the integrated circuit 400 so as to cover the solder 430.

FIG. 5 is a schematic drawing of an integrated circuit 500 containing a composition for containing metal ions in electronic devices according to a third aspect of a preferred embodiment of the present invention. As shown in FIG. 5, the inventive composition 100 may be contained in an underfill 510 which is deposited between the integrated circuit 500 and the package 520.The underfill 510 may be any conventional underfill 510 material and applied between the integrated circuit 500 and the package 520 so as to cover the solder 530.

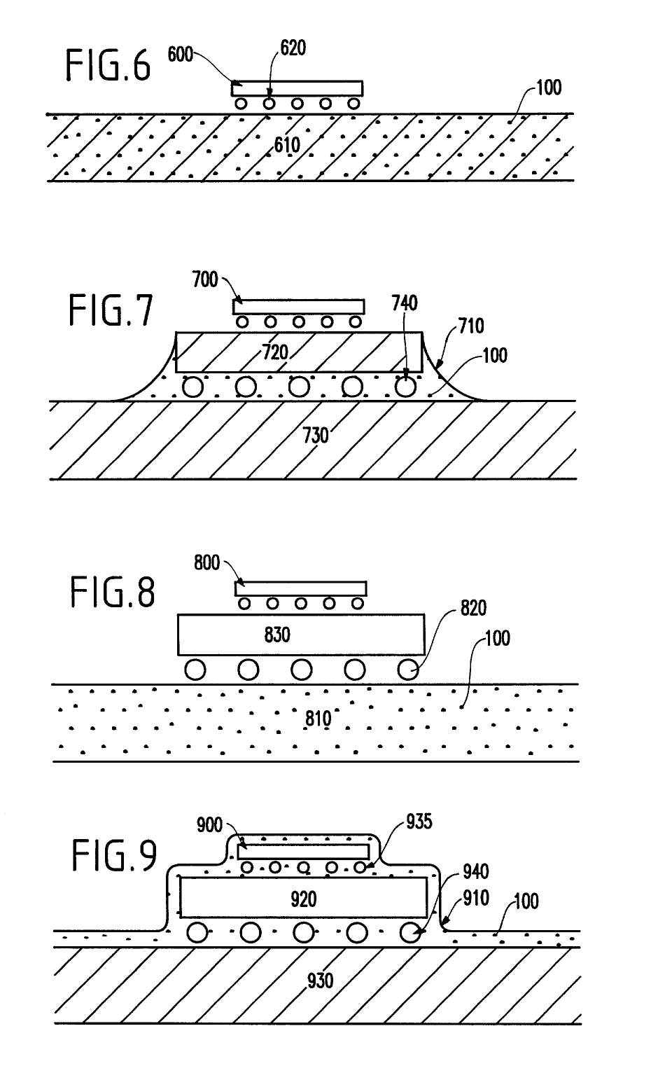

FIG. 6 is a schematic drawing of an integrated circuit 600 containing a composition for containing metal ions in electronic devices according to a fourth aspect of a preferred embodiment of the present invention. As shown in FIG. 6, the inventive composition 100 may be contained in an organic package 610 in close proximity to the solder 620 on the integrated circuit 100. The organic package 610 may be a dielectric such as epoxy, polyimide, teflon, etc..

FIG. 7 is a schematic drawing of an integrated circuit 700 containing a composition for containing metal ions in electronic devices according to a fifth aspect of a preferred embodiment of the present invention. As shown in FIG. 7, the inventive composition 100 may be contained in a package underfill 710 which is deposited between the package 720 and the printed circuit board 730. The package underfill 710 may be any conventional package underfill 710 material and applied so as to cover the solder 740 between the package 720 and the printed circuit board 730.

FIG. 8 is a schematic drawing of an integrated circuit 800 containing a composition for containing metal ions in electronic devices according to a sixth aspect of a preferred embodiment of the present invention. As shown in FIG. 8, the inventive composition 100 may be contained in the printed circuit board 810 in close proximity (i.e., about 50 to 500 microns) to the solder 820 between the package 830 and the printed circuit board 810.

FIG. 9 is a schematic drawing of a integrated circuit 900 containing a composition for containing metal ions in electronic devices according to a seventh aspect of a preferred embodiment of the present invention. As shown in FIG. 9, the inventive composition 100 may be contained in a conformal coating 910 which surrounds the entire integrated circuit 900 and package 920.

As shown in FIG. 9, the conformal coating 910 is deposited between the integrated circuit 900 and package 920 and between the package 920 and the printed circuit board 930. Furthermore, the conformal coating 910 may cover the solder 935 between the integrated circuit 900 and package 920 and the solder 940 between the package 920 and the printed circuit board 930.

Therefore, the inventive composition 100 may be contained within at least seven host elements: the scratch coat 310 , encapsulant 410, underfill 510, package 610, package underfill 710, printed circuit board 810 and conformal coating 910. The host element may be made of any conventional material commonly used in semiconductor manufacturing for protecting semiconductor devices, so long as the material does not interfere with the containment function of the inventive composition 100.

In still another aspect, alternating layers of conventional conformal coats and/or underfills may be interconnected with the inventive composition 100 in order to minimize leakage currents due to the ionic nature of a chelating agent.

In another aspect, the inventive composition 100 encapsulates the chelating agent 120 which is bonded to an immobile particle 110, in a water soluble gel or capsule, so that no leakage current is exhibited by the part but the chelating function of the inventive composition 100 is ‘activated’ upon contact with water. In other words, the capsule dissolves, releasing the inventive composition 100. Alternatively, the permeability and mobility of the inventive composition 100 in the saturated gel may be high in the presence of water.

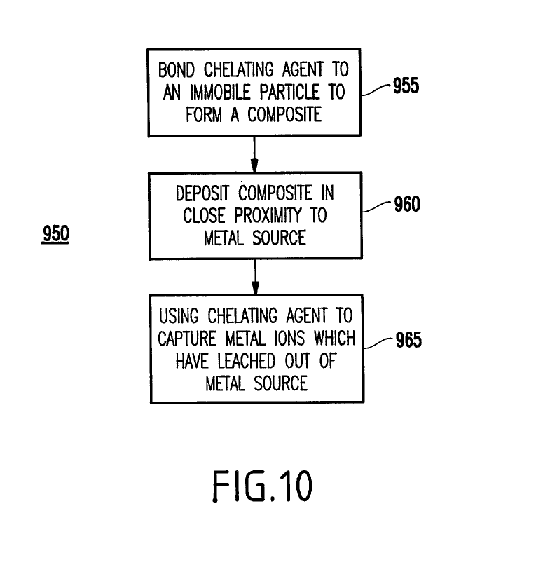

FIG. 10 is a flow diagram illustrating a preferred method 950 of containing metal ions in electronic devices according to a preferred embodiment of the present invention. As shown in FIG. 10, inventive method 950 includes bonding (955) a chelating agent to an immobile particle to form a composite. As explained above, the chelating agent may be have a single chelating group or multiple chelating groups. In addition, the chelating agent may have a general mode in which several metals are targeted or a specific mode in which a specific metal is targeted.

Further, the inventive method 950 includes depositing (955) the composite in close proximity to a metal source. As explained above, this may be accomplished by containing the composite within a scratch coat 310, encapsulant 410, underfill 510, package 610, package underfill 710, printed circuit board 810 or conformal coating 910.

Furthermore, the inventive method 950 includes using (960) the chelating agent to capture metal ions that have leached out of the metal source.

With its unique and novel features and designs, the inventive composition and method provide a means for preventing heavy metals from leaching out of an electronic device and into an aqueous environment when the device is discarded, thereby alleviating environmental concerns about discarded electronic devices. Therefore, until an adequate lead-free technology is developed, the claimed invention allows lead to be used in electronics device manufacturing without compromising the environment.

While the invention has been described in terms of preferred embodiments, those skilled in the art will recognize that the invention can be practiced with modification within the spirit and scope of the appended claims. Specifically, in addition to containing metal ions in metal solders in electronic devices, it should be understood that the present invention may be similarly utilized to contain metal ions within other metal sources.

What I claim is:

1. A composition for containing metal ions in an electronic device, comprising:
an immobile particle; and
a chelating agent which is bonded to said immobile particle.

2. The composition according to claim 1, wherein said chelating agent complexes with metal ions that leach out of metal sources within said electronic device.

3. The composition according to claim 1, wherein said chelating agent comprises one of an oxylate, ethylenediamine and ethylenediamine tetraacetate.

4. An electronic device having an integrated circuit with a composition for containing metal ions, said composition comprising:
an immobile particle; and
a chelating agent which is bonded to said immobile particle.

5. The electronic device according to claim 4, wherein said composition is contained within a scratch coat covering an active surface of said integrated circuit.

6. The electronic device according to claim 4, further comprising:
a package, to which said integrated circuit is bonded.

7. The electronic device according to claim 6, wherein said composition is contained within an encapsulant which is deposited over substantially an entire surface of said integrated circuit and between said integrated circuit and said package.

8. The electronic device according to claim 6, wherein said composition is contained within an underfill which is deposited between said integrated circuit and said package.

9. The electronic device according to claim 6, wherein said package comprises an organic package and wherein said composition is contained within said organic package.

10. The electronic device according to claim 6, further comprising:
a printed circuit board to which said package is bonded.

11. The electronic device according to claim 10, wherein said composition is contained within an underfill which is deposited between said package and said printed circuit board.

12. The electronic device according to claim 10, wherein said composition is contained within said printed circuit board.

13. The electronic device according to claim 10, wherein said composition is contained within a conformal coating which is deposited over said integrated circuit, said package and said printed circuit board.

14. A method of containing metals in an electronic product comprising:
bonding a chelating agent to an immobile particle to form a composite;
depositing said composite in close proximity to a metal source; and
using said chelating agent to capture metal ions which leach out of said metal source.

15. A composition consisting essentially of:
a chemically active moiety for chemically bonding with metal ions; and
a polymer which serves as an insoluble and immobile phase, to which said chemically active moiety is bonded.

16. The composition according to claim 15, wherein said chemically active moiety comprises a chelating agent.

17. The composition according to claim 15, wherein said metal ions comprise a variety of metal ions.

18. The composition according to claim 15, wherein said metal ions comprise specific metal ions.

19. The composition according to claim 15, wherein said metals comprise one of lead, antimony, bismuth and indium.

20. The composition according to claim 15, wherein said chelating agent comprises a plurality of chelating agents.

21. The composition according to claim 15, wherein said composition is contained within a dielectric phase of an electronic device.

22. The composition according to claim 15, wherein said composition is contained within an active surface protectant for an integrated circuit.

23. The composition according to claim 22, wherein said active surface protectant comprises a scratch coat protectant.

24. The composition according to claim 15, wherein said composition is contained within a die/chip protectant.

25. The composition according to claim 24, wherein said die/chip protectant comprises an encapsulant dielectric.

26. The composition according to claim 15, wherein said composition is contained within an underfill dielectric.

27. The composition according to claim 26, wherein said underfill dielectric is used in flip chip bonding.

28. The composition according to claim 15, wherein said composition is contained within an integrated circuit package organic dielectric.

29. The composition according to claim 28, wherein said organic dielectric comprises one of epoxy, polyimide, polytetrafluoroethylene laminate materials and epoxy molding compounds.

30. The composition according to claim 15, wherein said composition is contained within a package level underfill dielectric.

31. The composition according to claim 30, wherein said package level underfill dielectric comprises BGA underfill material.

32. The composition according to claim 15, wherein said composition is contained within a printed circuit board dielectric material.

33. The composition according to claim 32, wherein said printed circuit board dielectric material comprises epoxy, polyimide, polytetrafluoroethylene laminate materials and epoxy molding compounds.

34. The composition according to claim 15, wherein said composition is contained within a conformal coating dielectric.

35. The composition according to claim 34, wherein said conformal coating dielectric comprises an immersion coating for an electronic device.

36. The composition according to claim 15, wherein said chemically active moiety comprises one of an oxalate, ethylenediamine and ethylenediame tetraacetate.

37. The composition according to claim 15, wherein said chemically active moiety comprises more than one of an oxalate, ethylenediamine and ethylenediame tetraacetate.
